(19) United States
(12) Patent Application Publication
(10) Pub. No.: US 2019/0305151 A1
(43) Pub. Date: Oct. 3, 2019

(54) SOLAR CELL AND MANUFACTURING METHOD OF THE SAME

(71) Applicant: PANASONIC CORPORATION, Osaka (JP)

(72) Inventors: Shoji SATO, Osaka (JP); Toshiyuki SAKUMA, Osaka (JP); Mitsuhiro MATSUMOTO, Hyogo (JP)

(21) Appl. No.: 16/368,641

(22) Filed: Mar. 28, 2019

(30) Foreign Application Priority Data
Mar. 30, 2018 (JP) 2018-068005

(51) Int. Cl. H01L 31/0224; H01L 31/047; H01L 31/18

(52) U.S. Cl. CPC H01L 31/022425; H01L 31/18; H01L 31/047

(57) ABSTRACT

A solar cell includes a semiconductor substrate that includes: a first principal surface and a second principal surface; a first collecting electrode disposed above the first principal surface of the semiconductor substrate; a metal layer disposed below the second principal surface of the semiconductor substrate; and a second collecting electrode disposed below the metal layer. The first collecting electrode includes one or more first finger electrodes, and the second collecting electrode includes one or more second finger electrodes. The one or more first finger electrodes and the one or more second finger electrodes are substantially parallel to each other in a plan view.

### CROSS REFERENCE TO RELATED APPLICATION

This application claims the benefit of priority of Japanese Patent Application Number 2018-068005 filed on Mar. 30, 2018, the entire content of which is hereby incorporated by reference.

### BACKGROUND

### 1. Technical Field

The present disclosure relates to a solar cell and a manufacturing method of a solar cell.

### 2. Description of the Related Art

Conventionally, a solar cell has been developed as a photoelectric conversion device that converts light energy into electrical energy. A solar cell is expected to be a new energy source since a solar cell can directly convert unlimited sunlight into electricity, and electricity generated by a solar cell has a smaller environmental impact and is cleaner than electricity generated by fossil fuels.

Various examinations have been carried out to improve the photoelectric conversion efficiency of a solar cell. International Publication No. 2012/105155 discloses the photoelectric conversion device (solar cell) in which the transparent conductive film and the metallic film are stacked on the back surface-side of the photoelectric conversion unit (semiconductor substrate).

### SUMMARY

With regard to a solar cell, there is a demand for the reduction of stress applied to a semiconductor substrate included in the solar cell.

In view of this, the object of the present disclosure is to provide a solar cell which can reduce the stress applied to a semiconductor substrate, and the manufacturing method of the solar cell.

In order to achieve the object, a solar cell according to an aspect of the present disclosure includes: a semiconductor substrate that includes a first principal surface and a second principal surface opposite to the first principal surface; a first collecting electrode disposed above the first principal surface of the semiconductor substrate; a metal layer disposed below the second principal surface of the semiconductor substrate; and a second collecting electrode disposed below the metal layer. The first collecting electrode includes one or more first finger electrodes, the second collecting electrode includes one or more second finger electrodes, and the one or more first finger electrodes and the one or more second finger electrodes are substantially parallel to each other in a plan view.

In order to achieve the object, the manufacturing method of a solar cell according to an aspect of the present disclosure includes: preparing a semiconductor substrate that includes a first principal surface and a second principal surface opposite to the first principal surface; forming a metal layer below the second principal surface of the semiconductor substrate; and forming a first collecting electrode above the first principal surface of the semiconductor substrate and a second collecting electrode below the metal layer. The first collecting electrode includes one or more first finger electrodes, the second collecting electrode includes one or more second finger electrodes, and in forming the first collecting electrode and the second collecting electrode, the one or more first finger electrodes and the one or more second finger electrodes are formed substantially parallel to each other in a plan view.

According to an aspect of the present disclosure, it is possible to provide a solar cell which can reduce the stress applied to a semiconductor substrate, and the manufacturing method of the solar cell.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1A is a plan view illustrating a solar cell according to Embodiment 1 viewed from a light-receiving surface-side;

FIG. 1B is a plan view illustrating the solar cell according to Embodiment 1 viewed from a back surface-side;

FIG. 2 is a cross-sectional view of the solar cell according to Embodiment 1 taken along the line II-II in FIG. 1A;

FIG. 3 is a flow chart illustrating the manufacturing method of the solar cell according to Embodiment 1;

FIG. 4A is a plan view illustrating a solar cell according to Variation 1 of Embodiment 1 viewed from the back surface-side;

FIG. 4B is a plan view illustrating a solar cell according to Variation 2 of Embodiment 1 viewed from the back surface-side;

FIG. 4C is a plan view illustrating a solar cell according to Variation 3 of Embodiment 1 viewed from the back surface-side;

FIG. 4D is a plan view illustrating a solar cell according to Variation 4 of Embodiment 1 viewed from the back surface-side;

FIG. 5 is a plan view illustrating a solar cell according to Embodiment 2 viewed from the back surface-side;

FIG. 6A is a cross-sectional view of the solar cell according to Embodiment 2 taken along the line VI-VI in FIG. 5;

FIG. 6B is another example of a cross-sectional view of the solar cell according to Embodiment 2 taken along the line VI-VI in FIG. 5;

FIG. 7A is a plan view illustrating a solar cell according to Variation 1 of Embodiment 2 viewed from the back surface-side;

FIG. 7B is a cross-sectional view of a solar cell according to Variation 2 of Embodiment 2 taken along a line corresponding to the line VI-VI in FIG. 5;

FIG. 8 is a plan view illustrating a solar cell according to Embodiment 3 viewed from the back surface-side;

FIG. 9A is a cross-sectional view of the solar cell according to Embodiment 3 taken along the line IX-IX in FIG. 8;

FIG. 9B is another example of a cross-sectional view of the solar cell according to Embodiment 3 taken along the line IX-IX in FIG. 8;

FIG. 10 is a cross-sectional view of a solar cell according to a variation of Embodiment 3 taken along a line corresponding to the line IX-IX in FIG. 8;

FIG. 11 is a plan view illustrating a solar cell according to Embodiment 4 viewed from the back surface-side; and

FIG. 12 is a plan view illustrating a solar cell according to Embodiment 5 viewed from the back surface-side.

### DETAILED DESCRIPTION OF THE EMBODIMENTS

Hereinafter, an embodiment of the present disclosure will be described in detail with reference to the drawings. The exemplary embodiments described below each illustrate a particular example of the present disclosure. Accordingly, the numerical values, shapes, materials, elements, the arrangement and connection of the elements, processes, and the order of the processes, etc. indicated in the following exemplary embodiments are mere examples, and are not intended to limit the present disclosure. Therefore, among the elements in the following exemplary embodiments, elements not recited in any of the independent claims defining the most generic concept of the present disclosure are described as optional elements.

Note that the drawings are schematic diagrams, and do not necessarily provide strictly accurate illustrations. Throughout the drawings, the same sign is given to substantially the same element, and redundant description is omitted or simplified.

In addition, the expression “substantially XXX” is intended to include that which is considered to be practically XXX. Taking “substantially orthogonal” as an example, the expression is intended to include, not only that which is perfectly orthogonal, but also that which is considered to be practically orthogonal. In the present specification, “substantially” is meant to include a manufacture error and a dimensional tolerance.

Furthermore, throughout the drawings, the Z-axis direction is a direction perpendicular to the light-receiving surface of a solar cell, for example. The X-axis direction and the Y-axis direction are mutually orthogonal, and the X and the Y-axis directions are both orthogonal to the Z-axis direction. For example, in the following embodiments, “plan view” indicates a view from the Z-axis direction. In addition, in the following embodiments, “cross-sectional view” indicates viewing a section taken along a surface orthogonal to the light-receiving surface of the solar cell (for example, a surface defined by the Z-axis and the Y-axis) from a direction orthogonal to the section (for instance, from the X-axis direction).

### Embodiment 1

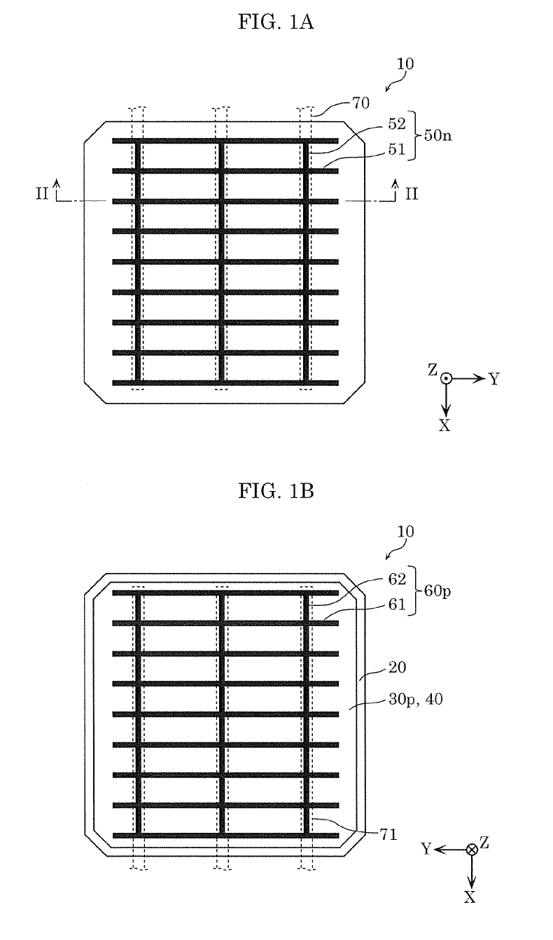

Hereinafter, a solar cell according to the present embodiment will be described with reference to FIG. 1A through FIG. 3.

### [1-1. Configuration of Solar Cell]

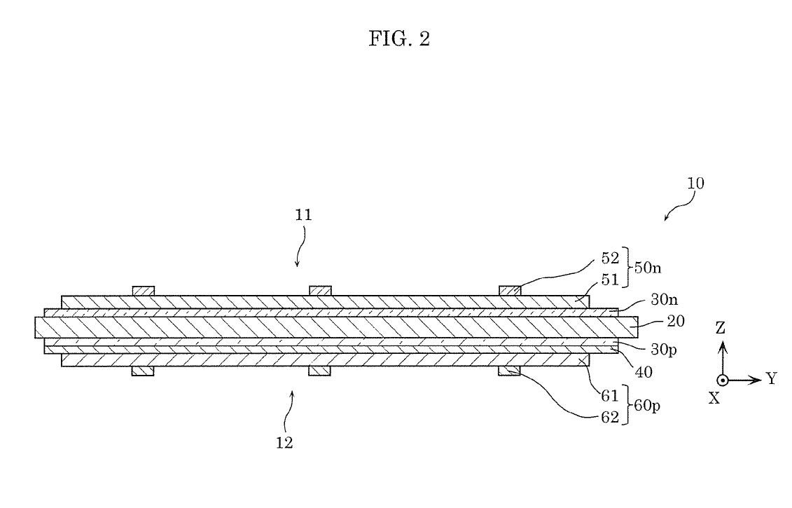

First, the configuration of a solar cell according to the present embodiment will be described with reference to FIG. 1A through FIG. 2.

FIG. 1A is a plan view illustrating solar cell 10 according to the present embodiment viewed from light-receiving surface 11-side. FIG. 1B is a plan view illustrating solar cell 10 according to the present embodiment viewed from back surface 12-side. FIG. 2 is a cross-sectional view of solar cell 10 according to the present embodiment taken along the line II-II in FIG. 1A.

As illustrated in FIG. 1A and FIG. 1B, solar cell 10 has a substantially quadrilateral shape in a plan view. For example, solar cell 10 has a 125 mm by 125 mm square shape with corners truncated. Note that the shape of solar cell 10 is not limited to a substantially quadrilateral shape.

As illustrated in FIG. 2, solar cell 10 is essentially configured as a p-n junction semiconductor. Solar cell 10 includes, for example, silicon substrate 20, n-side electrode 30n and n-side collecting electrode 50n disposed on a principal surface-side of silicon substrate 20 (the positive side of the Z-axis) in the stated order, and p-side electrode 30p, metal layer 40, and p-side collecting electrode 60p which are disposed on another principal surface-side of silicon substrate 20 (the negative side of the Z-axis) in the stated order. Note that in the present embodiment, the one of the principal surfaces of silicon substrate 20 is a surface of the main light-receiving surface-side of solar cell 10, and will also be referred to as light-receiving surface 11. The main light-receiving surface is a surface into which more than 50% of light that enters into solar cell 10 enters when a solar cell module is made using solar cells 10. In addition, in the present embodiment, the other principal surface of silicon substrate 20 is a surface opposite to the one of the principal surfaces of silicon substrate 20, and will also be referred to as back surface 12. Back surface 12 is a surface opposite to light-receiving surface 11. In addition, silicon substrate 20 is an example of a semiconductor substrate. Light-receiving surface 11 of silicon substrate 20 is an example of a first principal surface, and back surface 12 of silicon substrate 20 is an example of a second principal surface.

Silicon substrate 20 is a crystalline silicon substrate and is, for example, an n-type monocrystalline silicon substrate. Note that silicon substrate 20 is not limited to a monocrystalline silicon substrate (an n-type monocrystalline silicon substrate or a p-type monocrystalline silicon substrate) and may be a crystalline silicon substrate, such as a polycrystalline silicon substrate. The following describes an example in which silicon substrate 20 is an n-type monocrystalline silicon substrate. Note that in the present specification, p-type and n-type will also be referred to as first conductivity type and second conductivity type, respectively. For example, silicon substrate 20 is a silicon substrate having second conductivity type. In addition, silicon substrate 20 has a substantially quadrilateral shape in a plan view and a thickness of at most 150 μm, for example.

One of light-receiving surface 11 and back surface 12 of silicon substrate 20 may include a bumpy structure called a texture structure having pyramid shapes textured in two dimensions (not illustrated in the drawings). This enables solar cell 10 according to the present embodiment to effectively extend an optical path length of light in silicon substrate 20, thereby increasing the absorption of light which contributes to electricity generation without increasing the thickness of silicon substrate 20. For example, solar cell 10 can cause light having a wavelength with a small absorption coefficient to effectively contribute in electricity generation in silicon substrate 20.

In addition, although not illustrated in the drawings, an n-type semiconductor layer and a p-type semiconductor layer are disposed above and below silicon substrate 20, respectively. For example, the n-type semiconductor layer and the p-type semiconductor layer are disposed on light-receiving surface 11-side and back surface 12-side of silicon substrate 20, respectively.

The n-type semiconductor layer includes an i-type amorphous silicon layer (an intrinsic amorphous silicon layer) and an n-type amorphous silicon layer. The i-type amorphous silicon layer and the n-type amorphous silicon layer are stacked on light-receiving surface 11-side of silicon substrate 20 in the stated order. Note that the stacking of the i-type amorphous silicon layer and the n-type amorphous silicon layer here indicates that the i-type amorphous silicon layer and the n-type amorphous silicon layer are stacked in the positive direction of the Z-axis. The i-type amorphous silicon layer is a passivation layer disposed between silicon substrate 20 and the n-type amorphous silicon layer. The i-type amorphous silicon layer may include amorphous silicon having the content of less than 1×10¹⁹ cm⁻³ dopant. The n-type amorphous silicon layer is a semiconductor layer having the same conductivity type as silicon substrate 20. The n-type amorphous silicon layer may include amorphous silicon having the content of more than or equal to 5×10¹⁹ cm⁻³ n-type dopant, such as phosphorus (P) and arsenic (As). Note that the n-type semiconductor layer may include at least the n-type amorphous silicon layer.

The p-type semiconductor layer includes an i-type amorphous silicon layer (an intrinsic amorphous silicon layer) and a p-type amorphous silicon layer. The i-type amorphous silicon layer and the p-type amorphous silicon layer are stacked on back surface 12-side of silicon substrate 20 in the stated order. Note that the stacking of the i-type amorphous silicon layer and the p-type amorphous silicon layer here indicates that the i-type amorphous silicon layer and the p-type amorphous silicon layer are stacked in the negative direction of the Z-axis.

The i-type amorphous silicon layer is a passivation layer disposed between silicon substrate 20 and the p-type amorphous silicon layer. The p-type amorphous silicon layer is a semiconductor layer having a conductivity type different from silicon substrate 20. The p-type amorphous silicon layer may include amorphous silicon having the content of more than or equal to 5×10¹⁹ cm⁻³ p-type dopant, such as boron (B). Note that the p-type semiconductor layer may include at least the p-type amorphous silicon layer.

N-side electrode 30n and p-side electrode 30p are, for example, transparent conductive layers (transparent conductive oxide (TCO) films) which include a transparent conductive material. For example, the TCO films may include at least one type of metallic oxide having a polycrystalline structure, such as indium oxide (In₂O₃), zinc oxide (ZnO), tin oxide (SnO₂), or titanium oxide (TiO₂). A dopant, such as tin (Sn), zinc (Zn), tungsten (W), antimony (Sb), titanium (Ti), aluminum (Al), cerium (Ce), and gallium (Ga), may be doped with the above metallic oxide. An example of such metallic oxide is ITO which is In₂O₃ doped with Sn. The concentration of a dopant can be set to 0 to 20 percent by mass. Note that n-side electrode 30n is an example of a first transparent electrode layer and p-side electrode 30p is an example of a second transparent electrode layer.

P-side electrode 30p has a function of improving reflectance of incident light by preventing contact between the p-type semiconductor layer and metal layer 40 and the alloying of the p-type semiconductor layer and metal layer 40.

N-side collecting electrode 50n is an electrode which is disposed above n-side electrode 30n and collects light-receiving charges (electrons) created in a light-receiving area of silicon substrate 20. N-side collecting electrode 50n includes finger electrodes 51 which are linearly disposed in a direction orthogonal to the direction in which a line extends (see line 70 in FIG. 1A), and bus bar electrodes 52 which are connected to finger electrodes 51 and linearly disposed along a direction orthogonal to the direction in which finger electrodes 51 extend (for example, the direction in which line 70 extends), for example. Each of bus bar electrodes 52 is connected to line 70 on a one-to-one basis. Note that n-side collecting electrode 50n is an example of a first collecting electrode, and line 70 is an example of a first line. In addition, finger electrode 51 is an example of a first finger electrode, and bus bar electrode 52 is an example of a first bus bar electrode. Note that, in the present embodiment, n-side collecting electrode 50n includes bus bar electrode 52, but n-side collecting electrode 50n need not include bus bar electrode 52.

Metal layer 40 is a solid electrode which functions as an electrode unit which collects light-receiving charges transmitted from the n-type amorphous silicon layer via p-side electrode 30p. Metal layer 40 is a thin film made of a metallic material having high conductivity. In addition, metal layer 40 may have high light reflectance. More specifically, metal layer 40 may have high light reflectance to light having a wavelength with small absorption coefficient in silicon substrate 20. For example, metal layer 40 may have higher reflectance to the light in the infrared region than p-side electrode 30p. Accordingly, metal layer 40 can reflect incident light that has passed through silicon substrate 20 and the like towards light-receiving surface 11-side, for example.

The thickness of metal layer 40 (length in the Z-axis direction) may be up to a degree that the warping of solar cell 10 (specifically, silicon substrate 20) will not occur due to the stress applied by metal layer 40. The thickness of metal layer 40 is at most 600 nm, for example. In addition, metal layer 40 may be thinner than finger electrode 61 and p-side electrode 30p. When metal layer 40 includes Cu, the thickness of metal layer 40 may be at most 300 nm since Cu is of low resistance. This makes it possible to reduce the stress applied to silicon substrate 20. Note that the warping of solar cell 10 is the warping which occurs during heat treatment in the manufacturing processes, for example.

Although a metallic material included in metal layer 40 is not particularly limited, the metallic material is a metal, such as silver (Ag), copper (Cu), nickel (Ni), tin (Sn), aluminum (Al), titanium (Ti), rhodium (Rh), gold (Au), platinum (Pt), or chromium (Cr), or an alloy which includes at least one of the above-mentioned metals. More specifically, the metallic material may be a material having high reflectance to the light having a wavelength of approximately 800 nm to 1200 nm in the infrared region. In addition, metal layer 40 may be a stacked body which includes multiple films made of metallic materials mentioned above. Metal layer 40 may be a double-layer structure made of a Cu layer and an Sn layer, for example. Note that, in the present embodiment, metal layer 40 includes Cu. Furthermore, in the present embodiment, metal layer 40 does not include a conductive sheet (for example, a Cu sheet).

In addition, according to the present embodiment, p-side collecting electrode 60p is disposed below metal layer 40. P-side collecting electrode 60p is an electrode which collects light-receiving charges (electron holes) created in a light-receiving area of silicon substrate 20. P-side collecting electrode 60p includes, finger electrodes 61 which are linearly disposed in a direction orthogonal to the direction in which a line extends (see line 71 in FIG. 1B), and bus bar electrodes 62 which are connected to finger electrodes 61 and linearly disposed along a direction orthogonal to the direction in which finger electrodes 61 extend (for example, the direction in which line 71 extends), for example. Each of bus bar electrodes 62 is connected to line 71 on a one-to-one basis. Note that the present embodiment describes an example in which p-side collecting electrode 60p includes finger electrode 61 and bus bar electrode 62, but p-side collecting electrode 60p may include at least one of finger electrode 61 and bus bar electrode 62. In a plan view, p-side collecting electrode 60p may include an electrode which can be disposed in parallel with either finger electrode 51 or bus bar electrode 52, whichever is greater in number. For example, when the number of finger electrodes 51 is greater than the number of bus bar electrodes 52, or when n-side collecting electrode 50n does not include bus bar electrodes 52, p-side collecting electrode 60p may only include finger electrodes 61.

Although the total area of p-side collecting electrode 60p in a plan view is not limited, the total area of p-side collecting electrode 60p may be less than or equal to 30% of the area of the surface of back surface 12 of silicon substrate 20 from the viewpoint of reducing stress caused by metal layer 40, for example. The area of p-side collecting electrode 60p in a plan view may also be less than or equal to 20% or less than or equal to 10% of the area of the surface of back surface 12 of silicon substrate 20. In addition, from the viewpoint of the cost reduction of solar cell 10, the area of p-side collecting electrode 60p in a plan view may be less than or equal to 5% of the surface of back surface 12 of silicon substrate 20. Furthermore, the total area of p-side collecting electrode 60p in a plan view may be smaller than that of n-side collecting electrode 50n.

In addition, since metal layer 40 has lower resistance than p-side electrode 30p, the length of p-side collecting electrode 60p can be made shorter than that of n-side collecting electrode 50n. For example, the length of finger electrode 61 may be shorter than that of finger electrode 51. The length of bus bar electrode 62 may be shorter than that of bus bar electrode 52, also. The length of a finger electrode indicates the length of the finger electrode in the longitudinal direction. In the present embodiment, the length of a finger electrode indicates the length of the finger electrode in the X-axis direction. The length of a bus bar electrode indicates the length of the bus bar electrode in the longitudinal direction. In the present embodiment, the length of a bus bar electrode indicates the length of the bus bar electrode in the Y-axis direction.

Note that p-side collecting electrode 60p is an example of a second collecting electrode, and line 71 is an example of a second line. In addition, finger electrode 61 is an example of a second finger electrode, and bus bar electrode 62 is an example of a bus bar electrode (second bus bar electrode).

Note that finger electrode 51 and finger electrode 61 are substantially parallel to each other in a plan view. In addition, bus bar electrode 52 and bus bar electrode 62 are substantially parallel to each other in a plan view. Furthermore, finger electrode 61 and bus bar electrode 62 are substantially orthogonal to each other in a plan view. The present embodiment has described that each of finger electrode 61 and bus bar electrode 62 has a linear shape, but the shape is not limited to a perfect linear shape. For example, bus bar electrode 62 may have a nonlinear shape, which is not a linear shape, such as a zigzag shape that is a sawtooth shape.

Note that the number of finger electrodes 51 and 61 and bus bar electrodes 52 and 62 is not limited. There may be at least one of each finger electrodes 51 and 61 and bus bar electrodes 52 and 62 included. For example, the number of bus bar electrodes 52 and 62 may be the same as the number of lines 70 and 71, respectively. In the present embodiment, the number of each of bus bar electrodes 52 and 62 and lines 70 and 71 is three. Note that lines 70 and 71 are tab wiring which electrically connect two adjacent solar cells 10 to each other when a solar cell module is formed. In addition, n-side collecting electrode 50n and p-side collecting electrode 60p are illustrated as having the same shape, but the shapes of n-side collecting electrode 50n and p-side collecting electrode 60p are not limited to the above.

N-side collecting electrode 50n and p-side collecting electrode 60p each includes a low resistance conductive material, such as silver (Ag). For example, n-side collecting electrode 50n and p-side collecting electrode 60p can be formed by screen printing on a resin conductive paste (such as a silver paste) in which conductive fillers, such as silver particles, are dispersed in a binder resin in a predetermined pattern.

As described above, solar cell 10 according to the present embodiment is, for example, a heterojunction solar cell. This type of solar cell reduces defects in the interfaces between silicon substrate 20 and the n-type semiconductor layer and between silicon substrate 20 and the p-type semiconductor layer (heterojunction interfaces). Consequently, it is possible to improve the photoelectric conversion efficiency of solar cell 10.

Note that the passivation layers are not limited to i-type amorphous silicon layers. The passivation layers may be silicon oxide layers or silicon nitride layers, and the passivation layers need not be included.

### [1-2. Manufacturing Method of Solar Cell]

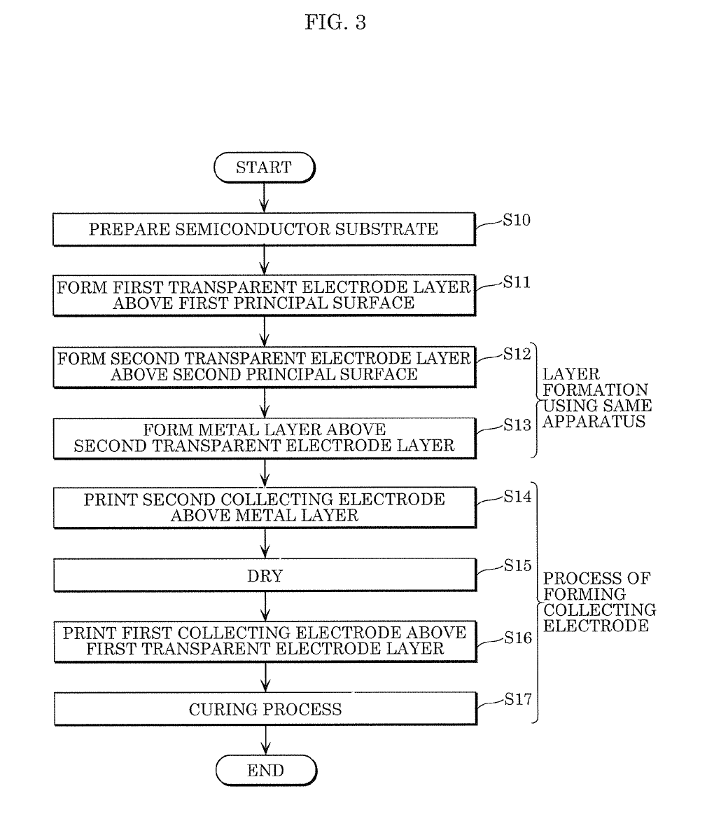

Next, the manufacturing method of solar cell 10 according to the present embodiment will be described with reference to FIG. 3.

FIG. 3 is a flow chart illustrating the manufacturing method of solar cell 10 according to the present embodiment.

First, as indicated in FIG. 3, a semiconductor substrate that is silicon substrate 20 is prepared (S10). Note that one of the surfaces of silicon substrate 20 prepared here may be treated to have a texture. Note that the texture can be formed by anisotropic etching on (100) plane of silicon substrate 20 using a potassium hydroxide (KOH) aqueous solution, for example.

In addition, the n-type semiconductor layer is disposed above light-receiving surface 11 of silicon substrate 20 and the p-type semiconductor layer is disposed below back surface 12 of silicon substrate 20. The n-type semiconductor layer and the p-type semiconductor layer are formed by plasma-enhanced chemical vapor deposition (PECVD), catalytic chemical vapor deposition (Cat-CVD), or sputtering, for example. The PECVD includes an RF plasma CVD method, a VHF plasma CVD method using high-frequency plasma, and a microwave plasma CVD method, and any one of the above methods can be used. In the present embodiment, the n-type semiconductor layer and the p-type semiconductor layer are formed using the RF plasma CVD method, for example.

The i-type amorphous silicon layer is formed as follows: (i) a gas containing silicon, such as silane (SiH₄), which is diluted with hydrogen is supplied to a film production chamber; (ii) the gas is turned into plasma by applying RF power to a parallel plate electrode placed in the film production chamber; and (iii) the gas that has been turned into plasma is supplied to at least one of light-receiving surface 11 and back surface 12 of silicon substrate 20 which are heated to at least 150° C. and at most 250° C.

The n-type amorphous silicon layer is formed as follows: (i) a mixed gas of a gas containing silicon, such as SiH₄, and a gas containing an n-type dopant, such as phosphine (PH₃), which is diluted with hydrogen is supplied to a film production chamber; (ii) the gas is turned into plasma by applying RF power to a parallel plate electrode placed in the film production chamber; and (iii) the gas that has been turned into plasma is supplied to light-receiving surface 11 of silicon substrate 20 which is heated to at least 150° C. and at most 250° C.

The p-type amorphous silicon layer is formed as follows: (i) a mixed gas mixed with a gas containing silicon, such as SiH₄, and a gas containing a p-type dopant, such as diborane (B₂H₆), which is diluted with hydrogen is supplied to a film production chamber; (ii) the gas is turned into plasma by applying RF power to a parallel plate electrode placed in the film production chamber; and (iii) the gas that has been turned into plasma is supplied to back surface 12 of silicon substrate 20 which is heated to at least 150° C. and at most 250° C. Note that the concentration of B₂H₆ in the mixed gas is, for example, 1%.

Next, n-side electrode 30n (an example of the first transparent electrode layer) is formed on light-receiving surface 11-side (an example of the first principal surface) of silicon substrate 20 (S11). More specifically, n-side electrode 30n is formed above the n-type amorphous silicon layer. For example, n-side electrode 30n is formed by solidifying metal paste used as coating liquid which has been dried after the metal paste is applied to the n-type amorphous silicon layer by screen printing or the like. The metal paste is made by adding particles having high light reflectance and conductivity to a binder, such as a light-transmissive resin. The light-transmissive resin here is an epoxy resin, for example. In addition, the particles included in the metal paste are particles of metal, such as Al, for example. In such cases, n-side electrode 30 includes a large number of conductive particles, and the conductivity of n-side electrode 30n is obtained by a large number of the conductive particles mutually contacting each other.

Next, p-side electrode 30p (an example of the second transparent electrode layer) is formed on back surface 20-side (an example of the second principal surface) of silicon substrate 20 (S12), and metal layer 40 is formed below p-side electrode 30p (S13). Steps S12 and S13 are performed consecutively. The same film forming apparatus may be used for the processes in steps S12 and S13.

In step S12, p-side electrode 30p is formed below the p-type amorphous silicon layer. Like n-side electrode 30n, p-side electrode 30p is formed by screen printing, for example. After p-side electrode 30p is formed, metal layer 40 is consecutively formed below p-side electrode 30p. Metal layer 40 is formed by screen printing, for example. For example, metal layer 40 is formed by solidifying metal paste used as coating liquid which has been dried after the metal paste is applied to p-side electrode 30p by screen printing or the like. The metal paste is made by adding particles having high light reflectance and conductivity to a binder, such as a light-transmissive resin. The light-transmissive resin here is an epoxy resin, for example. In addition, the metal materials described above are used for the particles included in the metal paste. In the present embodiment, Cu particles are used. In such cases, metal layer 40 includes a large number of conductive particles, and the conductivity of metal layer 40 is obtained by a large number of the conductive particles mutually contacting each other.

Next, p-side collecting electrode 60p (an example of the second collecting electrode) is printed in metal layer 40 (S14). P-side collecting electrode 60p includes a low resistance conductive material, such as silver (Ag). For example, p-side collecting electrode 60p (specifically, finger electrode 61 and bus bar electrode 62) can be formed by screen printing a resin conductive paste (such as a silver paste) in which conductive fillers, such as silver particles, are dispersed in a binder resin in a predetermined pattern. In the present embodiment, in a plan view, finger electrode 61 is disposed substantially parallel to finger electrode 51, and bus bar electrode 62 is disposed substantially parallel to bus bar electrode 52. After step S14, p-side collecting electrode 60p is dried for vaporizing the solvent contained in the printed resin conductive paste (S15).

Next, n-side collecting electrode 50n (an example of the first collecting electrode) is printed above n-side electrode 30n (S16). Like p-side collecting electrode 60p, n-side collecting electrode 50n can be formed by screen printing a resin conductive paste in a predetermined pattern. After step S16, the resin contained in the printed resin conductive paste is cured (S17).

The formation of p-side collecting electrode 60p prior to n-side collecting electrode 50n can prevent the formation of an oxide film over metal layer 40 during the heat treatment process after the material which forms n-side collecting electrode 50n is printed. More specifically, it is possible to prevent the formation of the oxide film in the portion of metal layer 40 disposed above p-side collecting electrode 60p. Accordingly, it is possible to improve the photoelectric conversion efficiency of solar cell 10 when compared to the case in which n-side collecting electrode 50n is formed prior to p-side collecting electrode 60p.

Note that steps S14 through S17 are example processes of forming the collecting electrodes.

Solar cell 10 according to the present embodiment is manufactured as described above. More specifically, solar cell 10 that includes collecting electrodes disposed above light-receiving surface 11 and below back surface 12, respectively, is manufactured. In addition, the collecting electrodes which are n-side collecting electrode 50n and p-side collecting electrode 60p are disposed substantially parallel to each other. Note that the disposition of n-side collecting electrode 50n and p-side collecting electrode 60p substantially parallel to each other indicates that at least finger electrodes 51 and 61 or bus bar electrodes 52 and 62 are parallel to each other.

### [1-3. Effect, Etc.]

As described above, solar cell 10 according to the present embodiment includes: silicon substrate 20 that includes a first principal surface and a second principal surface opposite to the first principal surface; n-side collecting electrode 50n disposed above the first principal surface of silicon substrate 20; metal layer 40 disposed below the second principal surface of silicon substrate 20; and p-side collecting electrode 60p disposed below metal layer 40. N-side collecting electrode 50n includes one or more finger electrodes 51. P-side collecting electrode 60p includes one or more finger electrodes 61. The one or more finger electrodes 51 and the one or more finger electrodes 61 are substantially parallel to each other in a plan view.

This makes it possible to reduce the warping of silicon substrate 20 caused by n-side collecting electrode 50n when compared to the case in which p-side collecting electrode 60p is not formed below the second principal surface (back surface 12) of silicon substrate 20. For example, when p-side collecting electrode 60p includes finger electrode 61, the direction of the warping of silicon substrate 20 caused by finger electrode 51 included in n-side collecting electrode 50n and the direction of the warping of silicon substrate 20 caused by finger electrode 61 included in p-side collecting electrode 60p are in opposite directions, and thus the warping cancel out each other. This reduces the warping of silicon substrate 20. Furthermore, due to the formation of low-resistant p-side collecting electrode 60p below metal layer 40, metal layer 40 can be made thinner when compared to the case in which p-side collecting electrode 60p is not formed below metal layer 40. This reduces the warping of silicon substrate 20 caused by metal layer 40. Consequently, according to solar cell 10 according to the present embodiment, it is possible to reduce the stress applied to silicon substrate 20. As described above, it is possible to reduce the cracking of silicon substrate 20 and the peeling of metal layer 40 caused by the warping of silicon substrate 20 due to the heat treatment in the manufacturing processes, for example.

In addition, p-side collecting electrode 60p includes one or more bus bar electrodes 62 disposed substantially orthogonal to one or more finger electrodes 61 in a plan view.

This improves current collecting efficiency when compared to the case in which p-side collecting electrode 60p only includes finger electrode 61. That is to say, it is possible to make metal layer 40 even thinner when compared to the case in which p-side collecting electrode 60p only includes finger electrode 61. Consequently, it is possible to further reduce the warping of silicon substrate 20 caused by metal layer 40.

In addition, as described above, the manufacturing method of solar cell 10 according to the present embodiment includes: a process of preparing silicon substrate 20 that includes a first principal surface and a second principal surface opposite to the first principal surface (S10); a process of forming n-side collecting electrode 30n above the first principal surface (S11); a process of forming metal layer 40 below the second principal surface of silicon substrate 20 (S13); and processes of forming n-side collecting electrode 50n above the first principal surface of silicon substrate 20 and p-side collecting electrode 60p below metal layer 40 (S14 through S17). N-side collecting electrode 50n includes one or more finger electrodes 51. P-side collecting electrode 60p includes one or more finger electrodes 61. In the processes of forming n-side collecting electrode 50n and p-side collecting electrode 60p, the one or more finger electrodes 51 and the one or more finger electrodes 61 are formed substantially parallel to each other in a plan view.

Accordingly, solar cell 10 manufactured using the above manufacturing method can yield the same advantageous effects as solar cell 10 described above.

In addition, between steps S11 and S13, the second transparent electrode layer is formed (S12). The processes of forming the second transparent electrode layer and the metal layer (S13) are performed using the same apparatus.

This makes it possible to readily manufacture solar cell 10 according to the present embodiment.

### Various Variations of Embodiment 1

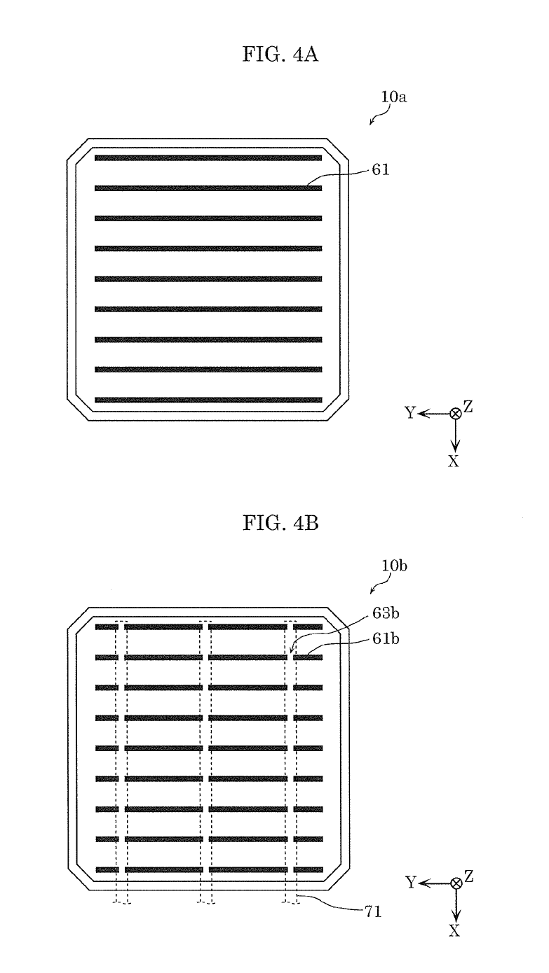

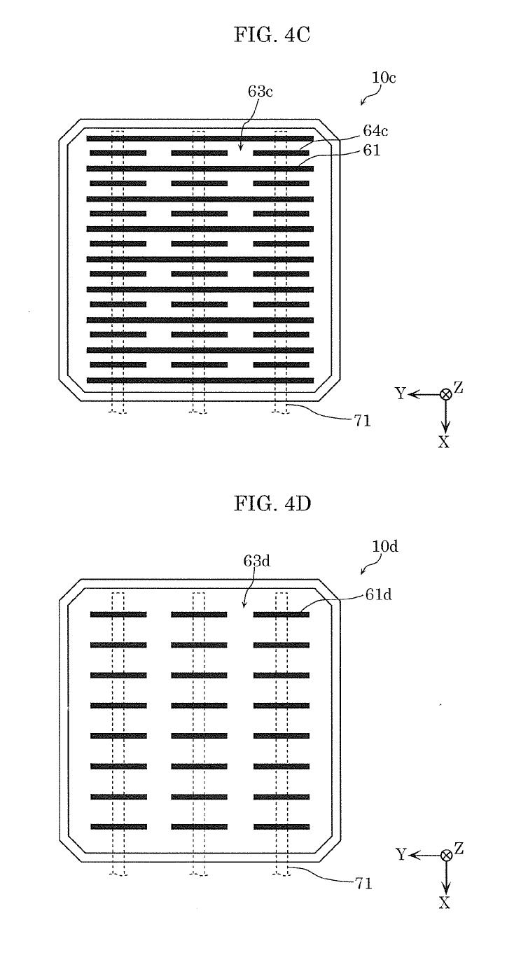

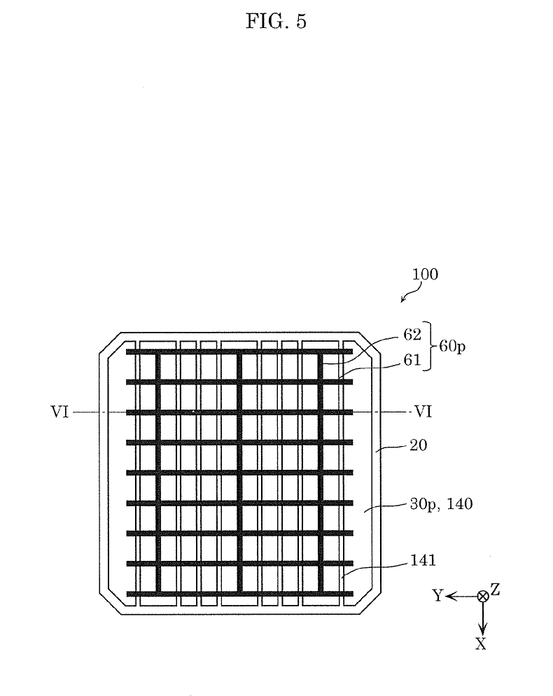

Hereinafter, solar cells according to various variations of Embodiment 1 will be described with reference to FIG. 4A through FIG. 4D. Note that in the various variations, the shape of a p-side collecting electrode disposed below silicon substrate 20 will be different from the shape of the p-side collecting electrode described in Embodiment 1.

FIG. 4A is a plan view illustrating solar cell 10a according to Variation 1 of Embodiment 1 viewed from back surface 12-side.

As illustrated in FIG. 4A, solar cell 10a does not include bus bar electrode 62. In the present variation, n-side collecting electrode 50n on light-receiving 11-side includes the number of finger electrodes 51 greater than the number of bus bar electrodes 52. For that reason, the warping of silicon substrate 20 caused by n-side collecting electrode 50n is mostly affected by finger electrodes 51. Consequently, p-side collecting electrode 60p which includes only finger electrodes 61, among finger electrodes 61 and bus bar electrodes 62, can effectively reduce the warping caused by n-side collecting electrode 50n. Note that it is not limited to finger electrodes 61 that are to be formed on back surface 12-side. When the number of bus bar electrodes 52 is greater than the number of finger electrodes 51, p-side collecting electrode 60p may include only bus bar electrodes 62, among finger electrodes 61 and bus bar electrodes 62. In addition, whether to include finger electrodes 51 or bus bar electrodes 52 may be determined according to the number of finger electrodes 51 and bus bar electrodes 52 or the area of finger electrodes 51 and bus bar electrodes 52.

FIG. 4B is a plan view illustrating solar cell 10b according to Variation 2 of Embodiment 1 viewed from back surface 12-side.

As illustrated in FIG. 4B, finger electrode 61b includes slit 63b in a position in which finger electrode 61b and line 71 overlap each other. That is to say, finger electrode 61b is not formed over slit 63b. The length of slit 63b (the length in the Y-axis direction) is shorter than the width of line 71 (the length in the Y-axis direction). This makes it possible to realize solar cell 10b which can reduce the decrease in current collecting efficiency and inexpensively reduce the warping of silicon substrate 20. Note that at least one finger electrode 61b among other finger electrodes 61b may include slit 63b. In addition, one finger electrode 61b may include at least one slit 63b.

FIG. 4C is a plan view illustrating solar cell 10c according to Variation 3 of Embodiment 1 viewed from back surface 12-side.

As illustrated in FIG. 4C, solar cell 10c includes, in addition to finger electrodes 61, finger electrodes 64c each of which is disposed in parallel to the direction to which finger electrodes 61 extend (the Y-axis direction), and includes an area in which at least a portion of electrode 64c overlaps line 71. Finger electrode 64c is shorter than finger electrode 61. Solar cell 10c includes slit 63c between adjacent finger electrodes 64c. That is to say, there is a difference in the density of finger electrode (the number of finger electrodes) in solar cell 10c between a portion close to line 71 and a portion far from line 71 (the portion between two lines 71). More specifically, the density of finger electrode in the portion close to line 71 is higher than that of finger electrode in the portion far from line 71. This makes it possible to realize solar cell 10c which can improve current collecting efficiency and reduce the warping of silicon substrate 20. Note that FIG. 4C illustrates an example that finger electrodes 61 and 64c are alternately disposed along the X-axis direction, but the dispositions of finger electrodes 61 and 64 are not limited to the above. In addition, solar cell 10c may include at least one finger electrode 64c.

FIG. 4D is a plan view illustrating solar cell 10d according to Variation 4 of Embodiment 1 viewed from back surface 12-side.

As illustrated in FIG. 4D, solar cell 10d includes slit 63d in a position in which finger electrode 61d and line 71 do not overlap each other. This makes it possible to realize solar cell 10d that can inexpensively reduce the warping of silicon substrate 20.

Note that each of finger electrodes 61, 61b, 64c, and 61d mentioned above is an example of the second collecting electrode.

### Embodiment 2

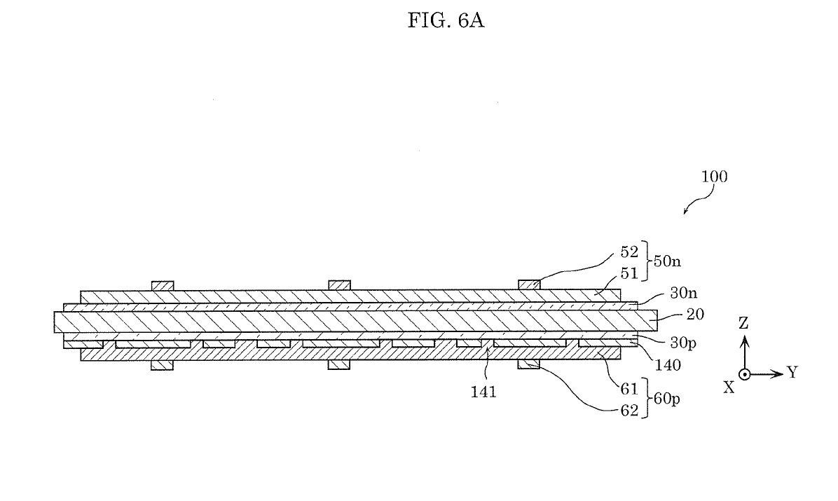

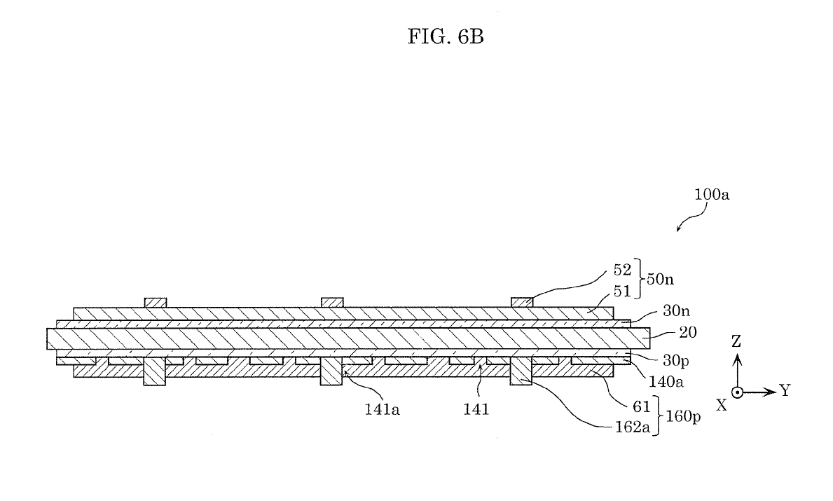

Hereinafter, a solar cell according to the present embodiment will be described with reference to FIG. 5 through FIG. 6B.

### [2-1. Configuration of Solar Cell]

FIG. 5 is a plan view illustrating solar cell 100 according to the present embodiment viewed from the back surface-side. FIG. 6A is a cross-sectional view of solar cell 100 according to the present embodiment taken along the line VI-VI in FIG. 5.

As illustrated in FIG. 5 and FIG. 6A, solar cell 100 according to the present embodiment includes slit 141 in metal layer 140. In a plan view, slit 141 extends in the direction substantially orthogonal to finger electrode 61. In other words, slit 141 extends in the direction substantially orthogonal to finger electrode 51 in a plan view. In addition, in a plan view, slit 141 extends in the direction substantially parallel to bus bar electrode 62. Accordingly, metal layer 140 is divided into regions each of which has a quadrilateral shape. In the present embodiment, each of the regions divided by slits 141 has a length extending in the direction orthogonal to finger electrodes 51 and 61 which is longer than a length extending in the direction parallel to finger electrodes 51 and 61.

Slit 141 includes at least a portion in which slit 141 and finger electrode 61 overlap each other. For example, slit 141 extends from the edge of metal layer 140 on the X-axis positive direction-side to the edge of metal layer 140 on the X-axis negative direction-side. The length of slit 141 (the length in the X-axis direction) is longer than the length of bus bar electrode 62, for example. In addition, the width of slit 141 (the length in the Y-axis direction) is at most 1 mm, for example. Note that the width of slit 141 may be the mean value, the median value, or the maximum value of the width of slit 141.

Slits 141 are disposed between two bus bar electrodes 62, among other bus bar electrodes 62. From the viewpoint of reducing the warping of silicon substrate 20 caused by metal layer 140, a large number of slits 141 may be included. Slits 141 are disposed between adjacent bus bar electrodes 62. The present embodiment illustrates an example in which three slits 141 are disposed between adjacent bus bar electrodes 62. In addition, in a plan view, slit 141 is also disposed outside the outermost bus bar electrode 62 closer to the edge of silicon substrate 20. In other words, each of bus bar electrodes 62 is sandwiched between slits 141.

Note that the number of slits 141 is not limited to the above. The number of slits 141 may be greater in a portion in which stress applied by metal layer 140 to silicon substrate 20 is stronger than in other portions. In other words, the regions of metal layer 140 divided by slits 141 may have different sizes. Slits 141 may be disposed such that the size of a region may be made smaller in a portion in which stress applied by metal layer 140 to silicon substrate 20 is stronger than in other portions.

As described in the present embodiment, although metal layer 140 includes slits 141, the formation of finger electrode 61 can reduce the decrease in current collecting efficiency and the warping of silicon substrate 20 caused by metal layer 140. Note that slits 141 may have different widths.

Slit 141 is a groove that penetrates metal layer 140. When solar cell 100 is viewed from back surface 12-side, p-side electrode 30p is exposed from a region of slit 141 in which slit 141 and finger electrode 61 do not overlap each other. Note that the exposure of p-side electrode 30p here indicates that p-side electrode 30p is visible in a plan view. In addition, as illustrated in FIG. 6A, in a plan view, a region of slit 141 in which slit 141 and finger electrode 61 overlap each other is filled with a material that forms finger electrode 61. That is to say, at least a portion of slit 141 is filled with finger electrode 61. Accordingly, finger electrode 61 can collect current even when metal layer 140 includes slit 141.

For example, slit 141 can be formed by changing the pattern of a screen printing plate used in the process of forming metal layer 140 (see S13 in FIG. 3). Note that slit 141 is an example of a slit (a first slit).

As described above, since slit 141 in metal layer 140 can reduce the warping of silicon substrate 20 caused by metal layer 140, metal layer 140 need not be made as thin as metal layer 140 in Embodiment 1. The thickness of metal layer 140 may be at least 600 nm and at most 1 μm, for example.

Note that, from the viewpoint of reducing stress caused by metal layer 140, metal layer 140 may include a large number of slits. Hereinafter, a solar cell that includes the number of slits greater than the number of slits included in the above solar cell 100 will be described with reference to FIG. 6B.

FIG. 6B is another example of a cross-sectional view of solar cell 100a according to Embodiment 2 taken along the line VI-VI in FIG. 5.

As illustrated in FIG. 6B, in a plan view, metal layer 140a includes at least a portion that overlaps bus bar electrode 52 and slit 141a which extends substantially parallel to bus bar electrode 52. In addition, bus bar electrode 162a is provided by filling slit 141a. That is to say, bus bar electrode 162a is formed in a position in which slit 141a is provided. Slit 141a is formed in the position in which slit 141a and bus bar electrode 162a overlap each other in a plan view. The width of slit 141a (the length in the Y-axis direction) is at most the width of bus bar electrode 162a (the length in the Y-axis direction). FIG. 6B illustrates an example in which the width of slit 141a and the width of bus bar electrode 162a are substantially equal.

Note that solar cell 100a may include at least one slit 141a. For example, when solar cell 100 is viewed from the direction to which bus bar electrode 162a extends (for example, the X-axis direction), slit 141a may be formed in a position in which slit 141a and bus bar electrode 162a disposed in substantially center among the other bus bar electrodes 162a overlap each other. Note that slit 141a is an example of a second slit. In addition, p-side collecting electrode 160p includes finger electrode 61 and bus bar electrode 162a.

### [2-2. Effects, Etc.]

As described above, metal layers 140 and 140a (hereinafter, also referred to as metal layer 140 etc.) included in solar cells 100 and 100a (hereinafter, also referred to as solar cell 100 etc.) according to the present embodiment includes slit 141 that extends substantially orthogonal to one or more finger electrodes 61 in a plan view.

The formation of slit 141 makes it possible to reduce the warping of silicon substrate 20 caused by metal layer 140 etc. Consequently, according to solar cell 100 etc. according to the present embodiment, it is possible to further reduce the stress applied to silicon substrate 20.

In addition, in a plan view, slit 141 is disposed substantially orthogonal to one or more finger electrodes 51.

Accordingly, since slit 141 is disposed substantially orthogonal to finger electrode 51, it is possible to reduce the peeling of metal layer 140 from silicon substrate 20 when the warping of silicon substrate 20 caused by finger electrode 51 occurs.

In addition, p-side collecting electrode 60p includes one or more finger electrodes 61 and one or more bus bar electrodes 62. Slits 141 are provided between two bus bar electrodes 62 among more than or equal to two bus bar electrodes 62.

This makes it possible for finger electrode 61 to collect current, thereby improving a degree of freedom in the position of slit 141 and the number of slit 141 to be formed. Consequently, it is possible to further reduce the stress applied to silicon substrate 20.

In addition, one or more finger electrodes 61 is formed by filling slit 141 in a position in which finger electrode 61 and slit 141 overlap each other.

This makes it possible to reduce the decrease in current collecting efficiency due to the formation of slit 141. Consequently, it is possible to maintain current collecting efficiency and reduce the stress applied to silicon substrate 20.

In addition, in a plan view, metal layer 140a further includes slit 141a whose at least a portion overlaps one or more bus bar electrodes 52 and which extends substantially parallel to one or more bus bar electrodes 52. One or more bus bar electrodes 162a is formed by filling slit 141a.

Accordingly, since slit 141a is also formed in a position in which bus bar electrode 162a is formed in a plan view, it is possible to further reduce the warping of silicon substrate 20 caused by metal layer 140a. Consequently, it is possible to maintain current collecting efficiency and further reduce the stress applied to silicon substrate 20.

### Various Variations of Embodiment 2

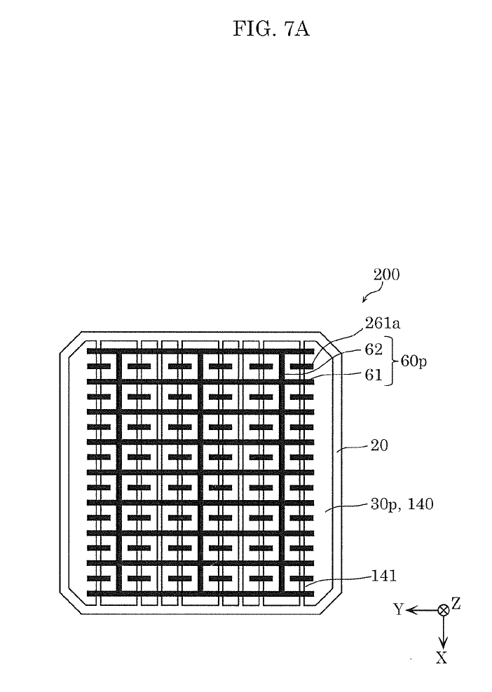

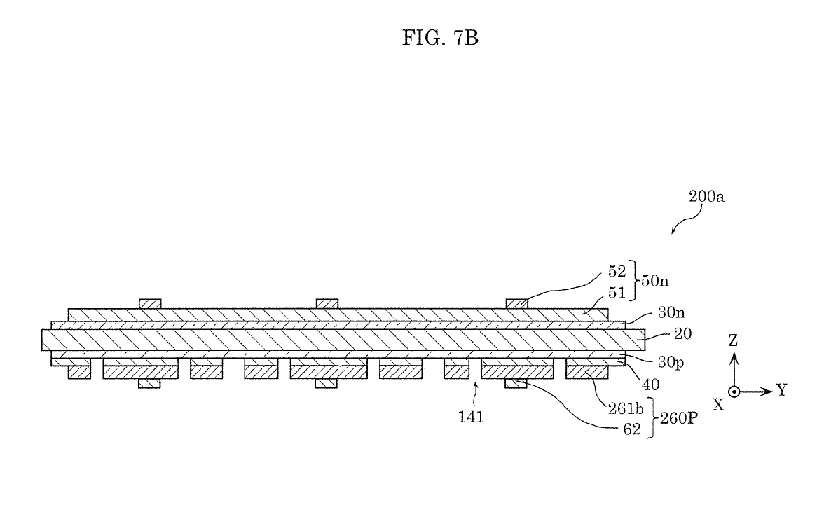

Hereinafter, solar cells according to various variations of Embodiment 2 will be described with reference to FIG. 7A and FIG. 7B.

FIG. 7A is a plan view illustrating solar cell 200 according to Variation 1 of Embodiment 2 viewed from back surface 12-side.

As illustrated in FIG. 7A, solar cell 200 according to the present variation further includes finger electrode 261a in addition to the configuration of solar cell 100 according to Embodiment 2. In a plan view, finger electrode 261a is disposed to span slit 141. For example, finger electrode 261a extends substantially parallel to finger electrode 61 and is shorter than finger electrode 61. This makes it possible to improve current collecting efficiency, because the formation of slit 141 in metal layer 140 causes an area which is originally not conductive to become conductive. For example, it is possible to effectively improve current collecting efficiency by disposing finger electrode 261a to span slit 141 which is disposed closer to bus bar electrode 62 among other slits 141. Note that, in a plan view, finger electrode 261a and bus bar electrode 61 do not overlap each other.

For example, finger electrode 261a can be formed by changing the pattern of a screen printing plate used in the process of forming p-side collecting electrode 60p (see S14 in FIG. 3). Finger electrode 261a and finger electrode 61 are made of the same material.

Note that metal layer 140 includes at least one finger electrode 261a. In addition, finger electrode 261a may be formed by filling slit 141 in a position in which finger electrode 261a and slit 141 overlap each other in a plan view. Furthermore, if finger electrode 261a is disposed to span slit 141 in a plan view, finger electrode 261a may be disposed at a predetermined angle relative to finger electrode 61.

FIG. 7B is a cross-sectional view of solar cell 200a according to Variation 2 of Embodiment 2 taken along a line corresponding to the line VI-VI in FIG. 5.

As illustrated in FIG. 7B, in a plan view, finger electrode 261b need not be disposed in a position in which finger electrode 261b and slit 141 overlap each other. That is to say, when solar cell 200a is viewed from back surface 12-side, p-side electrode 30p may be exposed from a region in which slit 141 is formed. This makes it possible to reduce the cost of manufacturing solar cell 200a compared to the cost of manufacturing solar cell 100 according to Embodiment 2. Note that, in a plan view, at least one position in which finger electrode 261b and slit 141 overlap each other among the other positions may have no finger electrode 261b formed. In addition, p-side collecting electrode 260p includes finger electrode 261b and bus bar electrode 62.

### Embodiment 3

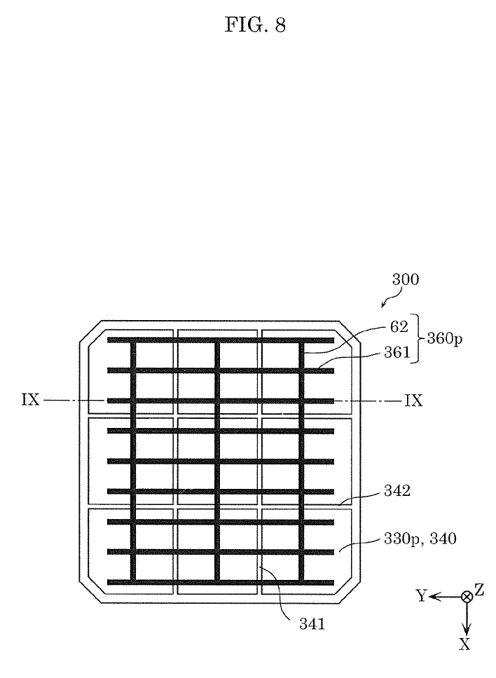

Hereinafter, a solar cell according to the present embodiment will be described with reference to FIG. 8.

### [3-1. Configuration of Solar Cell]

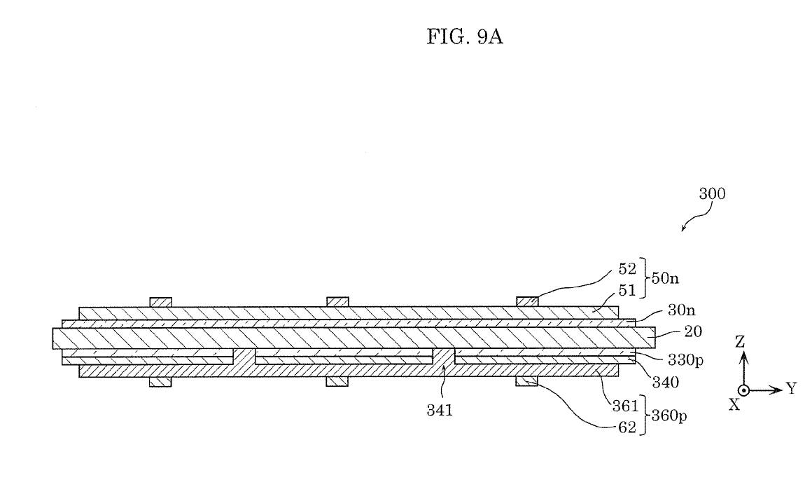

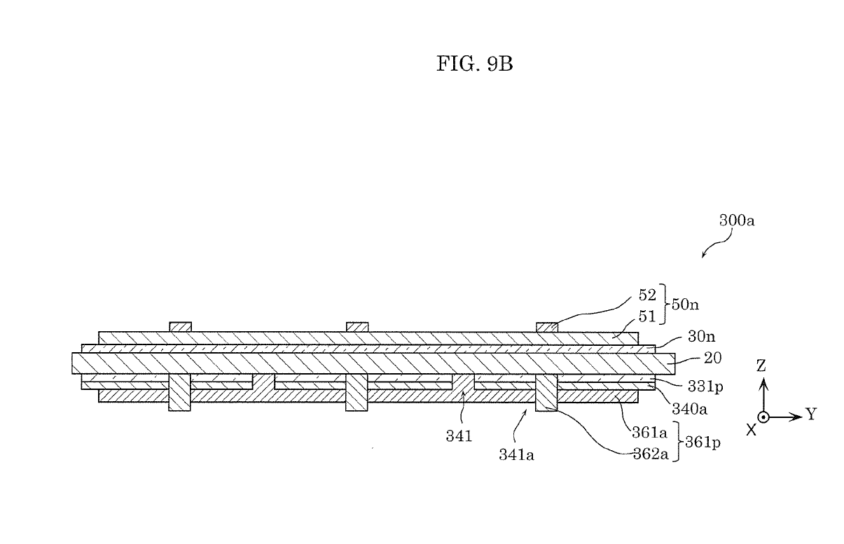

FIG. 8 is a plan view illustrating solar cell 300 according to the present embodiment viewed from back surface 12-side. FIG. 9A is a cross-sectional view of solar cell 300 according to the present embodiment taken along the line IX-IX in FIG. 8.

As illustrated in FIG. 8 and FIG. 9A, in the present embodiment, metal layer 340 includes slit 342 which is substantially parallel to finger electrode 361 and slit 341 which is substantially parallel to bus bar electrode 62. Slit 342 is longer than finger electrode 361, and slit 341 is longer than bus bar electrode 62.

Slits 341 and 342 are formed in metal layer 340 such that metal layer 340 does not include a region which is not electrically connected to p-side collecting electrode 360p. In other words, each of the regions divided by slits 341 and 342 may include at least one of finger electrode 361 and bus bar electrode 62. For example, slit 341 is disposed between adjacent bus bar electrodes 62, and slit 342 is disposed between adjacent finger electrodes 361. In addition, slits 341 may be disposed in the positions left and right each equally apart from bus bar electrode 62 disposed in the center among the other bus bar electrodes 62 (the left and the right in a plan view, and the positive and the negative directions of the Y-axis in FIG. 8), for example. Furthermore, slits 342 may be disposed in the positions above and below each equally apart from finger electrode 361 disposed in the center among the other finger electrodes 361 (the top and the bottom in a plan view, and the positive and the negative directions of the X-axis in FIG. 8), for example. In addition, slits 341 and 342 intersect at least at one point.

Note that the above has described an example in which metal layer 340 includes both slits 341 and 342, but the configuration of solar cell 300 is not limited to such a configuration. Metal layer 340 may include at least one of slit 341 and slit 342.

As illustrated in FIG. 9A, slit 341 is a groove which penetrates metal layer 340 and p-side electrode 330p. Slit 341 in p-side electrode 330p can be formed by changing the pattern of a screen printing plate used in the process of forming p-side electrode 330p (see S12 in FIG. 3). Note that each of slits 341 and 342 is an example of a slit (a first slit). In addition, p-side electrode 330p is an example of a second transparent electrode layer. Furthermore, p-side collecting electrode 360p includes finger electrode 361 and bus bar electrode 62.

Finger electrode 361 is formed by filling slit 341 in a region in which finger electrode 361 and slit 341 overlap each other in a plan view. That is to say, at least a portion of finger electrode 361 is in contact with silicon substrate 20 (specifically, the p-type amorphous silicon layer). According to the present embodiment, since finger electrode 361 contains resin, a metallic material (such as Ag) is not readily diffusible to silicon substrate 20-side when compared to the case in which a finger electrode does not contain resin (for example, a finger electrode formed by sintering). In addition, since the resistance of finger electrode 361 is lower than that of p-side electrode 330p, the contact of finger electrode 361 with silicon substrate 20 improves current collecting efficiency. Furthermore, when incident light enters finger electrode 361 which fills a portion of slit 341 from light-receiving surface 11-side, finger electrode 361 reflects the incident light.

Note that, from the viewpoint of reducing the stress caused by metal layer 340, metal layer 340 may include a large number of slits. Hereinafter, a solar cell that includes the number of slits greater than the number of slits included in the above solar cell 300 will be described with reference to FIG. 9B.

FIG. 9B is another example of a cross-sectional view of solar cell 300a according to Embodiment 3 taken along the line IX-IX in FIG. 8.

As illustrated in FIG. 9B, in a plan view, metal layer 340a includes at least a portion that overlaps bus bar electrode 52 and slit 341a which extends substantially parallel to bus bar electrode 52. In addition, bus bar electrode 362a is formed by filling slit 341a. That is to say, bus bar electrode 362a is formed in a position in which slit 341a is provided.

Slit 341a is a groove which penetrates metal layer 340a and p-side electrode 331p. Slit 341a in p-side electrode 331p can be formed by changing the pattern of a screen printing plate used in the process of forming p-side electrode 331p (see S12 in FIG. 3). Note that slit 341a is an example of a second slit. In addition, p-side electrode 331p is an example of the second transparent electrode layer.

Furthermore, p-side collecting electrode 361p includes finger electrode 361a and bus bar electrode 362a.

### [3-2. Effects, Etc.]

As described above, metal layer 340 of solar cells 300 and 300a (hereinafter, also referred to as solar cell 300 etc.) according to the present embodiment includes slits 341 and 342 which extend substantially parallel to at least one or more finger electrodes 361 or one or more bus bar electrodes 62 in a plan view.

This makes it possible to reduce the peeling of metal layer 340 from silicon substrate 20 even if the warping of silicon substrate 20 caused by n-side collecting electrode 50n occurs. For example, when slit 341 is formed, it is possible to reduce the peeling of metal layer 340 from silicon substrate 20 even if the warping of silicon substrate 20 caused by finger electrode 51 occurs. In addition, for example, when slit 342 is formed, it is possible to reduce the peeling of metal layer 340 from silicon substrate 20 even if the warping of silicon substrate 20 caused by bus bar electrode 52 occurs.

In addition, p-side collecting electrodes 360p contain resin. Furthermore, slit 341 is a groove which penetrates p-side electrode 330p.

This makes it possible to directly collect current from finger electrode 361 in a portion in which slit 341 is formed. Since the resistance of finger electrode 361 is lower than that of p-side electrode 330p, current collecting efficiency is further improved. Note that since finger electrode 361 contains resin, it is possible to reduce the diffusion of a metallic material contained in finger electrode 361 to silicon substrate 20-side.

In addition, slit 341a is a groove which penetrates p-side electrode 331p.

This makes it possible to directly collect current from bus bar electrode 362a in a portion in which slit 341a is formed. Since the resistance of bus bar electrode 362a is lower than that of p-side electrode 331p, current collecting efficiency is further improved.

### Variation of Embodiment 3

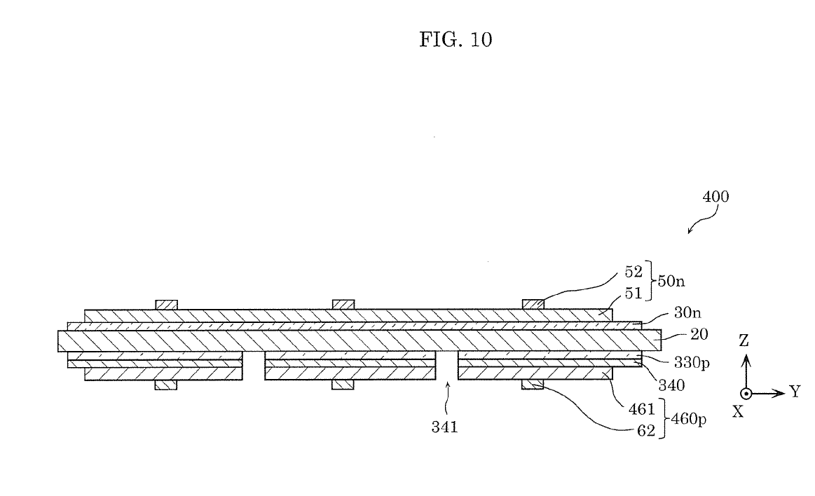

Hereinafter, a solar cell according to a variation of Embodiment 3 will be described with reference to FIG. 10.

FIG. 10 is a cross-sectional view of solar cell 400 according to a variation of Embodiment 3 taken along a line corresponding to the line IX-IX in FIG. 8.

As illustrated in FIG. 10, in a plan view, finger electrode 461 need not be formed in a position in which finger electrode 461 and slit 341 overlap each other. That is to say, when solar cell 400 is viewed from back surface 12 side, silicon substrate 20 may be exposed from a region in which slit 341 is formed. This makes it possible to reduce the cost of manufacturing solar cell 400 compared to the cost of manufacturing solar cell 300 according to Embodiment 3. Note that, in a plan view, at least one position in which finger electrode 461 and slit 341 overlap each other among the other positions may have no finger electrode 461 formed. In addition, p-side collecting electrode 460p includes finger electrode 461 and bus bar electrode 62.

### Embodiment 4

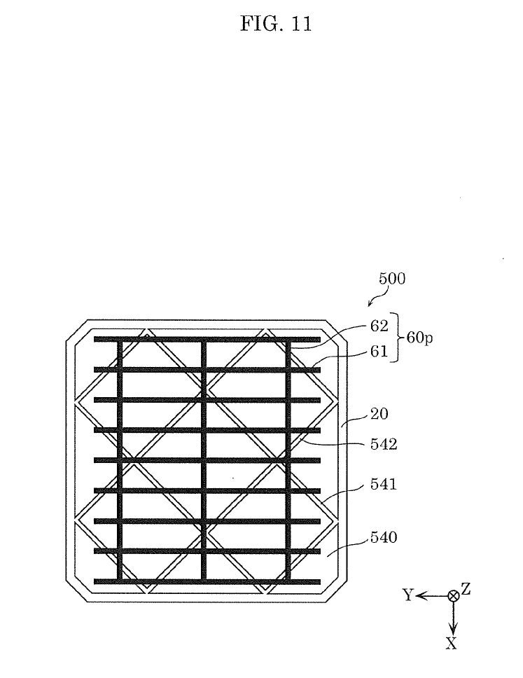

Hereinafter, a solar cell according to the present embodiment will be described with reference to FIG. 11.

### [4-1. Configuration of Solar Cell]

FIG. 11 is a plan view illustrating solar cell 500 according to the present embodiment viewed from back surface 12-side.

As illustrated in FIG. 11, slits 541 and 542 are not disposed substantially parallel to p-side collecting electrode 60p. More specifically, slits 541 and 542 are not disposed substantially parallel to finger electrode 61 and bus bar electrode 62, respectively. In other words, in a plan view, slits 541 and 542 intersect with at least one of finger electrode 61 and bus bar electrode 62 at a predetermined angle. Note that the predetermined angle does not include a right angle. For example, the predetermined angle includes from 5 degrees to 85 degrees, or may be from 40 degrees to 50 degrees. In the present embodiment, slits 541 and 542 extend in the direction substantially parallel to the their respective diagonal lines of solar cell 500, and intersect finger electrode 61 and bus bar electrode 62 at an angle of substantially 45 degrees. For example, each of slits 541 and 542 intersects with both finger electrode 61 and bus bar electrode 62. Slits 541 and 542 extend in mutually different directions and in the direction in which each of slits 541 and 542 intersects with both finger electrode 61 and bus bar electrode 62. Note that the predetermined angle indicates the angle of less than or equal to 90 degrees.

Note that each of slits 541 and 542 is an example of a slit (a first slit). In addition, solar cell 500 may include at least one of slits 541 and 542. In this case, one of slits 541 and 542 is an example of the slit (the first slit). Furthermore, solar cell 500 may include one of slits 541 and 542 which is substantially parallel to p-side collecting electrode 60p. In this case, the other of slits 541 and 542 is an example of the slit (the first slit).

Note that the above has described an example in which metal layer 540 is divided into substantially quadrilateral shapes by slits 541 and 542, but the shape is not limited to the above. Metal layer 540 may be divided into polygonal shapes. That is to say, slits 541 and 542 are not limited to be formed into substantially linear shapes. This improves a degree of freedom in the shape of slits 541 and 542 in a plan view. In addition, metal layer 540 may be divided by five or more slits disposed in mutually different directions in a plan view.

### [4-2. Effects, Etc.]

As described above, metal layer 540 included in solar cell 500 according to the present embodiment includes at least one of slits 541 and 542 which extends at a predetermined angle relative to one or more finger electrodes 61 in a plan view.

Accordingly, since a degree of freedom in the direction in which at least one of slits 541 and 542 is formed improves, it is possible to reduce the stress more appropriately. Consequently, according to solar cell 500 according to the present embodiment, when p-side collecting electrode 60p includes finger electrode 61, a balance between stress reduction and improvement in the output of current is more readily achieved.

In addition, in a plan view, metal layer 540 includes at least one of slit 541 and 542 which extends at a predetermined angle relative to at least one or more finger electrodes 61 or one or more bus bar electrodes 61 in a plan view.

Accordingly, since a degree of freedom in the direction of forming at least one of slits 541 and 542 improves, it is possible to reduce the stress more appropriately. Consequently, according to solar cell 500 according to the present embodiment, when p-side collecting electrode 60p includes finger electrode 61 and bus bar electrode 62, a balance between stress reduction and improvement in the output of current is more readily achieved.

In addition, in a plan view, metal layer 540 includes slits 541 and 542 which extend in the direction that intersects with at least one of p-side collecting electrodes 60p.

Accordingly, since a degree of freedom in the direction of forming slits 541 and 542 improves, it is possible to reduce the stress more appropriately. Consequently, according to solar cell 500 according to the present embodiment, a balance between stress reduction and improvement in the output of current is more readily achieved.

### Embodiment 5

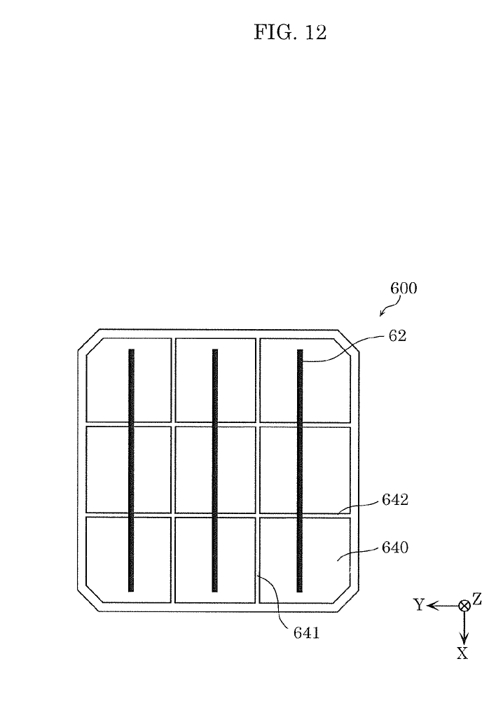

Hereinafter, a solar cell according to the present embodiment will be described with reference to FIG. 12.

### [5-1. Configuration of Solar Cell]

FIG. 12 is a plan view illustrating solar cell 600 according to the present embodiment viewed from back surface 12-side.

As illustrated in FIG. 12, solar cell 600 includes only bus bar electrode 62 as the second collecting electrode. That is to say, solar cell 600 does not include finger electrode on back surface 12-side. In addition, in the present embodiment, metal layer 640 includes slit 641 which is substantially parallel to bus bar electrode 62 and slit 642 which is substantially orthogonal to slit 641. Note that the present embodiment describes an example in which metal layer 640 includes both slits 641 and 642, but metal layer 640 may include at least slit 641. In a plan view, slit 641 is disposed substantially orthogonal to finger electrode 51.

Slits 641 and 642 are disposed in metal layer 640 such that there will be no region which is not electrically connected to bus bar electrode 62. In other words, each of the regions divided by slits 641 and 642 is electrically connected to at least one portion of bus bar electrode 62. More specifically, there is only one slit 641 disposed between adjacent bus bar electrodes 62. That is to say, in the present embodiment, the maximum number of slits 641 is a value subtracting one from the number of bus bar electrodes 62.

As described above, the dispositions of slits 641 and 642 in directions that do not prevent bus bar electrode 62 from collecting current can reduce stress caused by metal layer 640 without preventing bus bar electrode 62 from collecting current. In addition, although the warping of silicon substrate 20 which is caused by bus bar electrode 52 occurs, the disposition of slit 641 can also reduce the peeling of metal layer 640 from silicon substrate 20. Note that the number of slits 642 is not particularly limited. FIG. 12 illustrates an example in which metal layer 640 includes the same number of slits 641 and 642, but the number of slits 641 and 642 are not limited to this example. For example, the number of slits 642 can be greater than the number of slits 641.

Note that each of slits 641 and 642 is an example of a slit (a first slit).

### [5-2. Effects, Etc.]

As described above, each of p-side collecting electrodes included in solar cell 600 according to the present embodiment includes one or more bus bar electrodes, specifically, two or more bus bar electrodes 62. Slit 641 is disposed between two bus bar electrodes 62 among two or more bus bar electrodes 62.

Accordingly, even in the case in which solar cell 600 does not include a finger electrode on the back surface-side of solar cell 600, it is possible to reduce the peeling of metal layer 640 due to the warping of silicon substrate 20 caused by finger electrode 51 on the light-receiving surface-side.

### Other Embodiments

Although the above has described solar cells etc. according to the present disclosure based on the embodiments and the variations (hereinafter, also referred to as the embodiments etc.), the present disclosure is not limited to the embodiments etc. described above.

For example, although the above embodiments etc. have described examples in which the p-side and the n-side electrodes are formed by screen printing, yet the method of forming the p-side and the n-side electrodes is not limited to the screen printing. The p-side and the n-side electrodes may be formed by the film forming methods, such as evaporation and sputtering.

In addition, although the above embodiments etc. have described examples in which the n-type semiconductor layer is disposed on the main light-receiving surface-side of the solar cells, yet the configuration of the solar cells is not limited to this configuration. The solar cells may include the p-type semiconductor layer on the main light-receiving surface-side of the solar cells.

In addition, although the above embodiments etc. have described examples in which each of the first collecting electrode and the second collecting electrode includes both a finger electrode and a bus bar electrode, yet the configuration of the solar cells is not limited to this configuration. The first collecting electrode and the second collecting electrode may include at least one of the finger electrode and the bus bar electrode.

In addition, although the above embodiments etc. have described examples in which slits are formed using the pattern of a screen printing plate, yet the formation of the slits is not limited to the above. For example, the slits may be formed by etching the p-side electrode and the metal layer after the solid patterns of the p-side electrode and the metal layer are formed.

In addition, although the above embodiments etc. have described examples in which each of a finger electrode and a bus bar electrode has a fixed width, yet the width is not limited to the above. At least one of the finger electrode and the bus bar electrode may have a width thicker in a portion in which one of the finger electrode and the bus bar electrode intersects with a slit than in a portion in which one of the finger electrode and the bus bar electrode does not intersect with the slit in a plan view. This further improves current collecting efficiency.

In addition, the order of processes in the manufacturing method of the solar cells described in the above embodiments etc. is an example, and the order is not limited to the above. The processes may be in any order and some of the processes need not be performed.

In addition, the processes in the manufacturing method of the solar cells described in the above embodiments etc. may be performed as one process or each as a separate process. Note that the processes performed as one process are intended to include: the processes which are performed using one apparatus; the processes which are performed continuously; or the processes which are performed at the same place. Furthermore, the processes performed each as a separate process are intended to include: the processes which are performed using different apparatuses; the processes which are performed at different times (for example, different days); or the processes which are performed at different places.

The present disclosure also encompasses: embodiments achieved by applying various modifications conceivable to those skilled in the art to each of the embodiments etc.; and embodiments achieved by arbitrarily combining the structural elements and the functions of each of the embodiments etc. without departing from the essence of the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell, comprising:
a semiconductor substrate that includes a first principal surface and a second principal surface opposite to the first principal surface;
a first collecting electrode disposed above the first principal surface of the semiconductor substrate;
a metal layer disposed below the second principal surface of the semiconductor substrate; and
a second collecting electrode disposed below the metal layer, wherein
the first collecting electrode includes one or more first finger electrodes,
the second collecting electrode includes one or more second finger electrodes, and
the one or more first finger electrodes and the one or more second finger electrodes are substantially parallel to each other in a plan view.

2. The solar cell according to claim 1, wherein
the second collecting electrode further includes one or more bus bar electrodes disposed substantially orthogonal to the one or more second finger electrodes.

3. The solar cell according to claim 1, wherein
the metal layer includes a slit that extends substantially orthogonal to the one or more second finger electrodes in a plan view.

4. The solar cell according to claim 2, wherein
the metal layer includes a slit that extends substantially parallel to at least the one or more second finger electrodes or the one or more bus bar electrodes in a plan view.

5. The solar cell according to claim 1, wherein
the metal layer includes a slit that extends at a predetermined angle relative to the one or more second finger electrodes in a plan view.

6. The solar cell according to claim 2, wherein
the metal layer includes a slit that extends at a predetermined angle relative to at least the one or more second finger electrodes or the one or more bus bar electrodes in a plan view.

7. A method of manufacturing a solar cell, the method comprising:
preparing a semiconductor substrate that includes a first principal surface and a second principal surface opposite to the first principal surface;
forming a metal layer below the second principal surface of the semiconductor substrate; and
forming a first collecting electrode above the first principal surface of the semiconductor substrate and a second collecting electrode below the metal layer, wherein
the first collecting electrode includes one or more first finger electrodes,
the second collecting electrode includes one or more second finger electrodes, and
in forming the first collecting electrode and the second collecting electrode, the one or more first finger electrodes and the one or more second finger electrodes are formed substantially parallel to each other in a plan view.
